(19) United States
(12) Patent Application Publication
(10) Pub. No.: US 2025/0169365 A1
(43) Pub. Date: May 22, 2025

(54) Vibration Device

(71) Applicant: SEIKO EPSON CORPORATION, Tokyo (JP)

(72) Inventor: Koichi MIZUGAKI, Suwa (JP)

(21) Appl. No.: 18/954,903

(22) Filed: Nov. 21, 2024

(30) Foreign Application Priority Data
Nov. 22, 2023 (JP) 2023-197981

(51) Int. Cl. H10N 30/87; H03H 9/19; H10N 30/80; H10N 30/88

(52) U.S. Cl. CPC H10N 30/872; H03H 9/19; H10N 30/802; H10N 30/88

(57) ABSTRACT

A vibration device includes a semiconductor substrate having a first face and a second face in a front-to-back relationship with the first face, the semiconductor substrate having a first through hole that extends from the first face to the second face, a first conductive layer disposed on the second face of the semiconductor substrate and overlapping the first through hole in plan view, an organic resin formed on a side face of the first through hole and the first face of the semiconductor substrate, the first face being located around an opening of the first through hole, the opening being close to the first face, a first wire formed on a surface of the first conductive layer, the surface being exposed from the first through hole, on a surface of the organic resin, and in a first region of the first face of the semiconductor substrate, the first region not overlapping the organic resin, and a vibration element bonded to a portion of the first wire, the portion being disposed in the first region, through a first bonding member.

The present application is based on, and claims priority from JP Application Serial Number 2023-197981, filed Nov. 22, 2023, the disclosure of which is hereby incorporated by reference herein in its entirety.

### BACKGROUND

### 1. Technical Field

The present disclosure relates to a vibration device.

### 2. Related Art

For example, JP-A-2020-195116 discloses a vibration device in which a first terminal is disposed on the first face and a second terminal is disposed on the second face of a silicon substrate with a through hole, a resin layer is disposed between the wire that electrically couples the first terminal and the second terminal, the wire passing through the through hole, and the inner wall of the through hole, and a vibration element is bonded on the first terminal. Disposition of a resin layer between the wire and the inner wall of the through hole makes it possible to reduce the parasitic capacitance formed between the silicon substrate and the wire.

However, in the vibration device described in JP-A-2020-195116, a resin layer is also disposed between the first terminal and the first face, so that when the vibration element is heated and pressurized, and bonded on the first terminal, the electrode film of the first terminal is deformed due to the soft resin layer, resulting in a possibility of causing cracks in the electrode film and breaking the wire.

### SUMMARY

According to an aspect of the present disclosure, a vibration device includes a semiconductor substrate having a first face and a second face in a front-to-back relationship with the first face, the semiconductor substrate having a first through hole that extends from the first face to the second face, a first conductive layer disposed on the second face of the semiconductor substrate and overlapping the first through hole in plan view, an organic resin formed on a side face of the first through hole and the first face of the semiconductor substrate, the first face being located around an opening of the first through hole, the opening being close to the first face, a first wire formed on a surface of the first conductive layer, the surface being exposed from the first through hole, on a surface of the organic resin, and in a first region of the first face of the semiconductor substrate, the first region not overlapping the organic resin, and a vibration element bonded to a portion of the first wire, the portion being disposed in the first region, through a first bonding member.

### BRIEF DESCRIPTION OF THE DRAWINGS

FIG. 1 is a perspective view illustrating the schematic structure of a vibration device of the first embodiment.

FIG. 2 is a plan view illustrating the schematic structure of the vibration device of the first embodiment.

FIG. 3 is a cross-sectional view taken along line III-III in FIG. 2.

FIG. 4 is a cross-sectional view taken along line IV-IV in FIG. 2.

FIG. 5 is a plan view illustrating the schematic structure of a vibration device for the second embodiment.

FIG. 6 is a cross-sectional view taken along line VI-VI in FIG. 5.

FIG. 7 is a cross-sectional view taken along line VII-VII in FIG. 5.

### DESCRIPTION OF EMBODIMENTS

### 1. First Embodiment

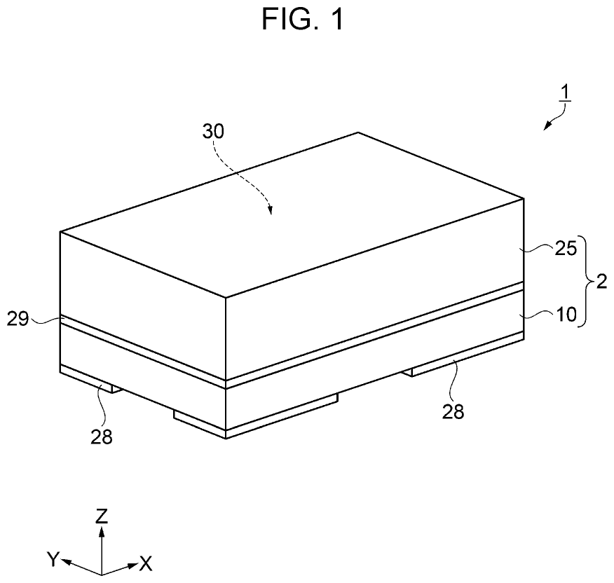

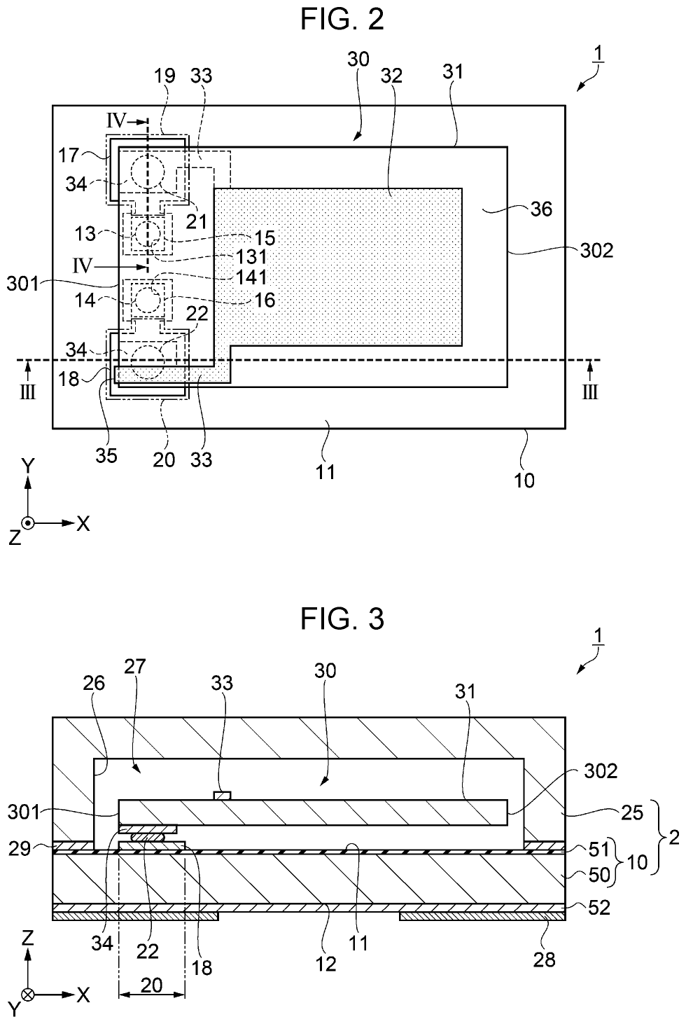

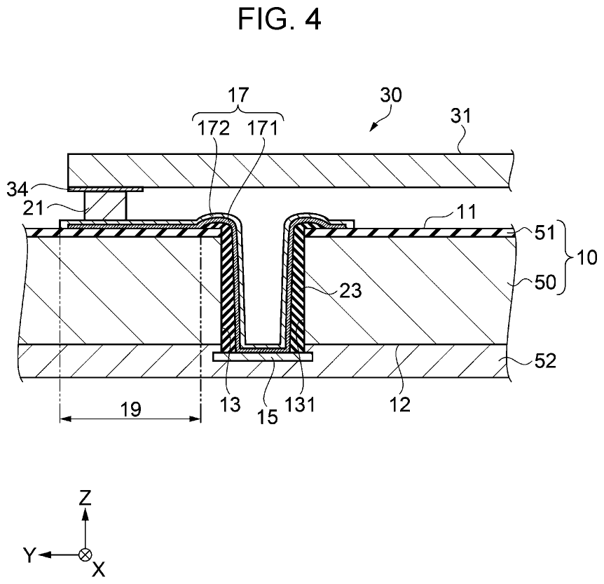

An oscillator including a vibration element 30 and an oscillation circuit 52 is taken as an example of a vibration device 1 of the first embodiment, and is described with reference to FIGS. 1 to 4. In FIGS. 2 and 4, for convenience in describing the internal configuration of the vibration device 1, a state in which a lid 25 is removed is illustrated. For convenience of description, the X, Y, and Z axes are illustrated as three mutually orthogonal axes in the perspective view, the plan view, and the cross-sectional view described below. A direction along the X axis is referred to as the “X direction”, a direction along the Y axis as the “Y direction”, and a direction along the Z axis as the “Z direction”. The arrow side of each axis is referred to as the “positive side” and the side opposite the arrow is referred to as the “negative side”. The positive side in the Z direction is referred to as “up” and the negative side in the Z direction as “down”. In the present embodiment, the first direction is the X direction and the second direction is the Y direction.

The vibration device 1 includes a semiconductor substrate 10, the lid 25, and the vibration element 30, as illustrated in FIGS. 1, 2, and 3. The semiconductor substrate 10 and the lid 25 constitute a package 2 that houses the vibration element 30.

The semiconductor substrate 10 includes a silicon substrate 50 and a silicon oxide layer 51, and the silicon oxide layer 51 is provided on the top face of the silicon substrate 50. The semiconductor substrate 10 is a rectangular flat plate in plan view in the Z direction. The semiconductor substrate 10 has a first face 11 that is the top face of the silicon oxide layer 51, and a second face 12 that is in a front-to-back relationship with the first face 11, and has a first through hole 13 and a second through hole 14 that extend from the first face 11 to the second face 12. The first through hole 13 and the second through hole 14 are disposed side by side in the Y direction on the negative side of the semiconductor substrate 10 in the X direction in plan view, with the first through hole 13 disposed on the positive side in the Y direction and the second through hole 14 disposed on the negative side in the Y direction.

The oscillation circuit 52 is provided on the second face 12 of the semiconductor substrate 10, and a first conductive layer 15 is provided at the position where the first conductive layer 15 overlaps the first through hole 13 in plan view, and a second conductive layer 16 is provided at the position where the second conductive layer 16 overlaps the second through hole 14 in plan view. The first conductive layer 15 and the second conductive layer 16 are electrically coupled to the oscillation circuit 52. The oscillation circuit 52 oscillates the vibration element 30 to generate the frequency of a reference signal such as a clock signal. A plurality of external terminals 28 that supplies a voltage to the oscillation circuit 52 and outputs the oscillation frequency is provided on the bottom face of the oscillation circuit 52.

A first wire 17 electrically coupling a first bonding member 21 that bonds the vibration element 30 and the first conductive layer 15, and a second wire 18 electrically coupling a second bonding member 22 that bonds the vibration element 30 and the second conductive layer 16 are provided on the first face 11 of the semiconductor substrate 10. The first wire 17 is disposed at a position where the first wire 17 overlaps the first through hole 13 in plan view and extends in the positive Y direction, and the second wire 18 is disposed at a position where the second wire 18 overlaps the second through hole 14 in plan view and extends in the negative Y direction. The first bonding member 21 extends in the positive Y direction of the first wire 17 and is disposed in a first region 19, which will be described below, where an organic resin 23 is not disposed, and the second bonding member 22 extends in the negative Y direction of the second wire 18 and is disposed in a second region 20, which will be described below, where the organic resin 23 is not disposed. A metal bump such as Au (gold) or solder is preferred as the constituent material of the first bonding member 21 and the second bonding member 22. The first wire 17 is drawn outward from the region where the organic resin 23 is disposed. The first region 19 is a region where the organic resin 23 is not disposed and where the first wire 17 is provided. That is, the first region 19 is a region in which the first wire 17 is provided, the region not overlapping the organic resin 23. The second wire 18 is drawn outward from the region where the organic resin 23 is disposed. The second region 20 is a region where the organic resin 23 is not disposed and where the second wire 18 is provided. That is, the second region 20 is a region in which the second wire 18 is provided, the region not overlapping the organic resin 23.

When a direction from one end 301 toward the other end 302 of the vibration element 30 is the first direction and the direction orthogonal to the first direction and along a main face 36 of the vibration element is the second direction, the first bonding member 21 is located on the positive side in the Y direction that is one side of the Y direction, that is, the second direction, in plan view, and the second bonding member 22 is located on the negative side of the Y direction that is the other side of the Y direction, that is, the second direction, in plan view. In the Y direction, the first through hole 13 and the second through hole 14 are disposed between the first bonding member 21 and the second bonding member 22, and the range in which the first through hole 13 and the second through hole 14 are located overlaps a range in which the first bonding member 21 is disposed and a range in which the second bonding member 22 is disposed in the X direction that is the first direction.

The lid 25 is rectangular in plan view in the Z direction and has a recess 26 that opens toward the semiconductor substrate 10. The lid 25 is bonded to the first face 11 of the semiconductor substrate 10 via a bonding member 29. The vibration element 30 is housed in a housing space 27, that is a space surrounded by the lid 25 and the semiconductor substrate 10. The housing space 27 is airtight and under reduced pressure, preferably closer to a vacuum. This reduces viscous resistance and improves the vibration characteristics of the vibration element 30. However, the atmosphere in the housing space 27 is not limited in particular.

The constituent material of the lid 25 is preferably silicon. When the semiconductor substrate 10 and the lid 25 are made of silicon, the coefficients of linear expansion of the semiconductor substrate 10 and the lid 25 are equal, so that generation of thermal stress caused by thermal expansion is suppressed to obtain the vibration device 1 with excellent vibration characteristics. In addition, since the vibration device 1 can be formed by a semiconductor process, the vibration device 1 can be manufactured with high precision and can be made smaller.

A method of bonding the semiconductor substrate 10 and the lid 25 is a method of bonding the semiconductor substrate 10 and the lid 25 via the bonding member 29 such as glass frit, but the present disclosure is not limited to this method, and a metallic eutectic bonding method can be used, in which metal films deposited on the first face 11 of the semiconductor substrate 10 and a face of the lid 25, the face being in contact with the semiconductor substrate 10, are bonded to each other. Alternatively, an activation bonding method can be used in which the surface of the first face 11 of the semiconductor substrate 10 and the surface of a metal film such as Au deposited on a face of the lid 25, the face being in contact with the semiconductor substrate 10 are activated by plasma irradiation to bond the semiconductor substrate 10 and the lid 25. Alternatively, the method can be a direct bonding that does not require any inclusions between two bonding surfaces of the same material.

The vibration element 30 has the one end 301 and the other end 302, and a portion of the vibration element 30, the portion close to the one end 301, is bonded through the first bonding member 21 and the second bonding member 22. The vibration element 30 includes a vibration substrate 31 made of a quartz crystal substrate, and an excitation electrode 32 and a pad electrode 34 that are provided on the main face 36 of the vibration substrate 31.

The excitation electrode 32 is provided on the top face of the vibration substrate 31, and the excitation electrode 32 and two pad electrodes 34 at positions where the respective pad electrodes 34 overlap the first bonding member 21 and the second bonding member 22 in plan view are provided on the bottom face of the vibration substrate 31. The excitation electrode 32 on the top face of the vibration substrate 31 is electrically coupled to the pad electrode 34 on the negative side in the Y direction, the pad electrode 34 being provided on the bottom face of the vibration substrate 31, via a lead electrode 33 and a side face electrode 35 close to the one end 301. The excitation electrode 32 on the bottom face of the vibration substrate 31 is electrically coupled to the pad electrode 34 on the positive side in the Y direction via the lead electrode 33. The two respective pad electrodes 34 are bonded to the semiconductor substrate 10 via the first bonding member 21 and the second bonding member 22. The area of the excitation electrode 32 on the top face is the same as the area of the excitation electrode 32 on the bottom face, and they overlap with each other in plan view.

In the present embodiment, the vibration substrate 31 is made of quartz crystal, but the present disclosure is not limited to this and may be made of piezoelectric single-crystal materials such as lithium niobate, lithium tantalate, lithium tetraborate, langasite, potassium niobate, gallium phosphate, or others, or the vibration substrate 31 may be made of piezoelectric single-crystal materials other than the above. The vibration element 30 is not limited to a piezoelectric drive type vibration element, but can also be an electrostatic drive type vibration element using electrostatic forces.

Next, the configuration of the first through hole 13 and the first wire 17 will be described with reference to FIG. 4.

The semiconductor substrate 10 has the first through hole 13 overlapping the first conductive layer 15 in plan view as illustrated in FIG. 4.

The organic resin 23 that serves as an insulating layer is formed on a side face 131 of the first through hole 13 and on the first face 11 of the semiconductor substrate 10, the first face 11 being around an opening of the first through hole 13, the opening being close to the first face 11. By using the organic resin 23 as an insulating layer, the organic resin 23 can be formed such that the opening width on the second face 12 of the semiconductor substrate 10 is narrower than the opening width on the first face 11 of the semiconductor substrate 10.

With such a configuration, since the organic resin 23 has a tapered shape with a wider opening width on the first face 11, it is possible to improve the coverage of the first wire 17 disposed on the organic resin 23 and to lower the electrical resistance of the first wire 17.

On the organic resin 23, in other words, on the surface of the organic resin 23, the first wire 17 is formed over the first conductive layer 15. The first wire 17 is formed on a surface of the first conductive layer 15, the surface being exposed from the first through hole 13, on a surface of the organic resin 23, and in the first region 19 of the first face 11 of the semiconductor substrate 10, the first region 19 not overlapping the organic resin 23. A portion of the first region 19 overlaps the first bonding member 21. Accordingly, the vibration element 30 is bonded to a portion of the first wire 17, the portion being disposed in the first region 19, through the first bonding member 21. In other words, the vibration element 30 can be bonded through the first bonding member 21 at a position that is away from the first face 11 of the semiconductor substrate 10, the first face 11 being around the opening of the first through hole 13 where the organic resin 23 is formed, and that does not overlap the organic resin 23.

The first wire 17 includes a first wire layer 171 and a second wire layer 172 which is disposed on the first wire layer 171. The first wire layer 171 is, for example, a laminated film made of titanium tungsten (TiW)/copper (Cu). For example, at least one of copper (Cu) and aluminum (Al) may be included instead of copper (Cu).

The second wire layer 172 is formed to cover the entire first wire layer 171. The second wire layer 172 is, for example, a laminated film made of titanium tungsten (TiW)/gold (Au).

Thus, the use of copper (Cu) for the first wire layer 171 and gold (Au) for the second wire layer 172 makes it possible to lower the electrical resistance and suppress the deterioration of the vibration characteristics of the vibration element 30. In addition, since the first wire 17 has a two-layer structure with the first wire layer 171 and the second wire layer 172, the resistance of the first wire 17 that electrically couples the vibration element 30 and the first conductive layer 15 can be lowered.

Furthermore, since the first wire layer 171 made of copper (Cu) or the like is formed as the lower layer for the second wire layer 172, the cost can be reduced, compared with the conductive layer made of gold (Au) alone, which has low resistance.

The configuration of the second through hole 14 and the second wire 18 is the same as that of the first through hole 13 and the first wire 17, and the second through hole 14 is formed to so as to overlap the second conductive layer 16 in plan view.

The organic resin 23 is formed on a side face 141 of the second through hole 14 and on the first face 11 of the semiconductor substrate 10, the first face 11 being around an opening of the second through hole 14, the opening being close to the first face 11.

The second wire 18 is formed on a surface of the second conductive layer 16, the surface being exposed from the second through hole 14, on a surface of the organic resin 23, and in of the first face 11 of the semiconductor substrate 10, the second region 20 not overlapping the organic resin 23.

The vibration element 30 is bonded to a portion of the second wire 18, the portion being disposed in the second region 20, through the second bonding member 22. In other words, the vibration element 30 can be bonded through the second bonding member 22 at a position that is away from the first face 11 of the semiconductor substrate 10, the first face 11 being around the opening of the second through hole 14 where the organic resin 23 is formed, and that does not overlap the organic resin 23.

As described above, in the vibration device 1 of the present embodiment, the first bonding member 21 and the second bonding member 22 are disposed in the first region 19 and the second region 20 of the first wire 17 and the second wire 18 that electrically couple the first conductive layer 15 and the second conductive layer 16 that are electrically coupled to the oscillation circuit 52, and the first bonding member 21 and the second bonding member 22 that bond the vibration element 30, the first region 19 and the second region 20 not overlapping the organic resin 23, respectively. Therefore, when the vibration element 30 is bonded on the first wire 17 and the second wire 18 by heating or pressurization through the first bonding member 21 and the second bonding member 22, decoupling due to, for example, deformation of or cracks in the first wire 17 and the second wire 18 can be reduced. Therefore, the vibration device 1 with excellent reliability of electrical coupling can be obtained.

### 2. Second Embodiment

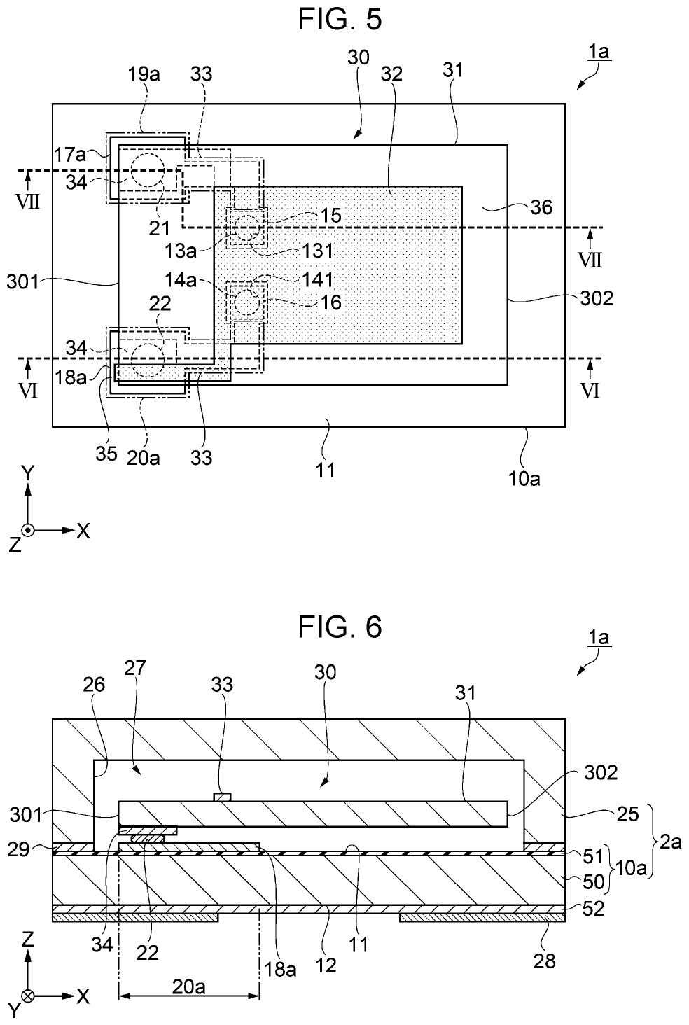

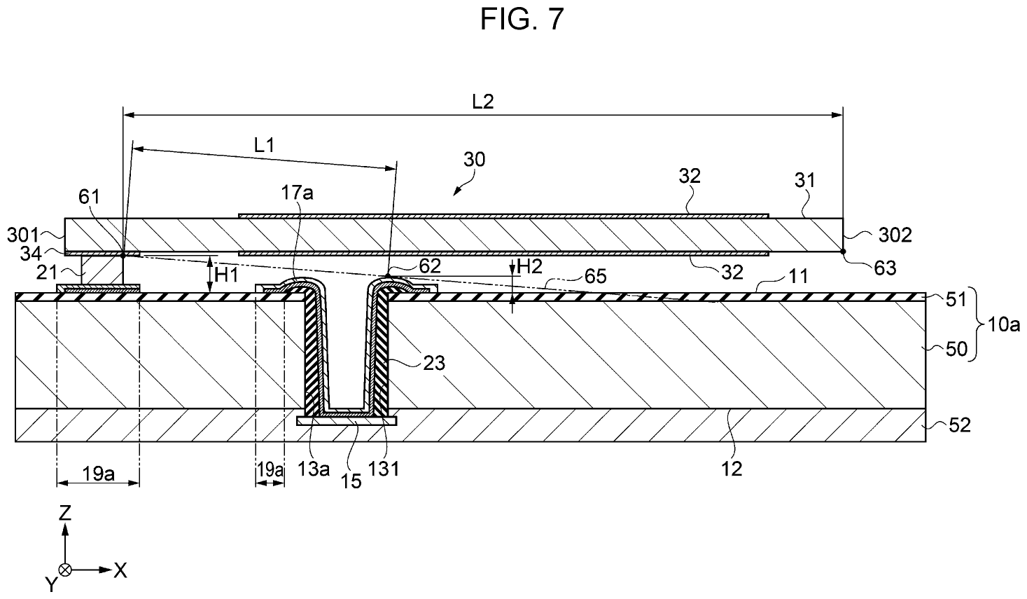

Next, a vibration device 1a of the second embodiment is described with reference to FIGS. 5, 6, and 7. In FIGS. 5 and 7, for convenience in illustrating the internal configuration of the vibration device 1, a state in which the lid 25 is removed is illustrated.

The vibration device 1a of the present embodiment is similar to the vibration device 1 of the first embodiment, except that the positions where the first through hole 13 and the second through hole 14 are disposed and the configurations of the first wire 17 and the second wire 18 are different from those of the vibration device 1 of the first embodiment. The description will focus on the differences from the aforementioned first embodiment, and similar items will be omitted with the same symbols.

The vibration device 1a includes a semiconductor substrate 10a, the lid 25, and the vibration element 30, as illustrated in FIGS. 5 and 6. The semiconductor substrate 10a and the lid 25 constitute a package 2a that houses the vibration element 30.

A first wire 17a electrically couples the first bonding member 21 that bonds the vibration element 30 and the first conductive layer 15, and a second wire 18a electrically couples the second bonding member 22 that bond the vibration element 30 and the second conductive layer 16 are provided on the first face 11 of the semiconductor substrate 10a. The first wire 17a is disposed at a position where the first wire 17a overlaps a first through hole 13a in plan view and extends in the positive Y direction and then in the negative X direction, and the second wire 18a is disposed at a position where the second wire 18a overlaps a second through hole 14a in plan view and extends in the negative Y direction and then in the negative X direction.

The first bonding member 21 extends in the negative X direction of the first wire 17a and is disposed in a first region 19a where the organic resin 23 is not disposed, and the second bonding member 22 extends in the negative X direction of the second wire 18a and is disposed in a second region 20a where the organic resin 23 is not disposed.

The first through hole 13a and the second through hole 14a are disposed between the first bonding member 21 and the second bonding member 22 in the Y direction. The range in which the first through hole 13a and the second through hole 14a are disposed is located on the positive side in the X direction, which is closer to the other end 302 of the vibration element 30 than is the range in which the first bonding member 21 and the second bonding member 22 are disposed in the X direction.

As illustrated in FIG. 7, the vibration device 1a of the present embodiment satisfies (H1−H2)×L2/H1>L1 where, in cross-sectional view, H1 is a length between the first face 11 of the semiconductor substrate 10a and a first portion 61 that is an end of a face of the first bonding member 21, the face being close to the vibration element 30, the end being close to the other end 302, L1 is a distance, in an imaginary line 65 passing through the first portion 61, touching a second portion 62 of the first wire 17a on the organic resin 23 formed on the first face 11 around the first through hole 13a, and intersecting the first face 11, between the first portion 61 and the second portion 62, H2 is a length between the first face 11 of the semiconductor substrate 10a and the second portion 62, and L2 is a distance between the first portion 61 and a corner 63 of the other end 302 of the vibration element 30, the corner 63 being close to the semiconductor substrate 10a. When satisfying (H1−H2)×L2/H1>L1, it is possible to reduce contact between the excitation electrode 32 provided on the bottom face of the vibration element 30 and the first wire 17a or the second wire 18a when the vibration element 30 is bonded to the semiconductor substrate 10a or when a shock is applied to the vibration device 1a.

With such a configuration, it is possible to reduce contact between the excitation electrode 32 and the first wire 17a or the second wire 18a when the vibration element 30 is bonded or when a shock is applied, and the same effect as in the first embodiment can be obtained.

What is claimed is:

1. A vibration device comprising:
a semiconductor substrate having a first face and a second face in a front-to-back relationship with the first face, the semiconductor substrate having a first through hole that extends from the first face to the second face;
a first conductive layer disposed on the second face of the semiconductor substrate and overlapping the first through hole in plan view;
an organic resin formed on a side face of the first through hole and the first face of the semiconductor substrate, the first face being located around an opening of the first through hole, the opening being close to the first face;
a first wire formed on a surface of the first conductive layer, the surface being exposed from the first through hole, on a surface of the organic resin, and in a first region of the first face of the semiconductor substrate, the first region not overlapping the organic resin; and
a vibration element bonded to a portion of the first wire, the portion being disposed in the first region, through a first bonding member.

2. The vibration device according to claim 1, wherein
the vibration element has one end and an other end, and a portion of the vibration element, the portion being close to the one end, is bonded through the first bonding member, and
when the first through hole is located closer to the other end than is the first bonding member,
(H1−H2)×L2/H1>L1
where, in cross-sectional view,
H1 is a length between the first face of the semiconductor substrate and a first portion that is an end of a face of the first bonding member, the face being close to the vibration element, the end being close to the other end,
L1 is a distance, in an imaginary line passing through the first portion, touching a second portion of the first wire on the organic resin formed on the first face around the first through hole, and intersecting the first face, between the first portion and the second portion,
H2 is a length between the first face of the semiconductor substrate and the second portion, and
L2 is a distance between the first portion and a corner of the other end of the vibration element, the corner being close to the semiconductor substrate.

3. The vibration device according to claim 1, further comprising:
a second conductive layer and a second wire, wherein
the semiconductor substrate has a second through hole that extends from the first face to the second face,
the second conductive layer is disposed on the second face of the semiconductor substrate and overlaps the second through hole in plan view,
the organic resin is formed on a side face of the second through hole and on the first face of the semiconductor substrate, the first face being located around an opening of the second through hole, the opening being close to the first face,
the second wire is formed on a surface of the second conductive layer, the surface being exposed from the second through hole, on a surface of the organic resin, and in a second region of the first face of the semiconductor substrate, the second region not overlapping the organic resin, and
the vibration element is bonded to a portion of the second wire, the portion being disposed in the second region, through a second bonding member.

4. The vibration device according to claim 3, wherein
when a direction from one end to an other end of the vibration element is a first direction and a direction orthogonal to the first direction and along a main face of the vibration element is a second direction,
the first bonding member is located on one side of the second direction in plan view,
the second bonding member is located on an other side of the second direction in plan view, and
in the second direction, the first through hole and the second through hole are located between the first bonding member and the second bonding member.

5. The vibration device according to claim 3, wherein
when a direction from one end to an other end of the vibration element is a first direction and a direction orthogonal to the first direction and along a main face of the vibration element is a second direction,
the first bonding member is located on one side of the second direction in plan view,
the second bonding member is located on an other side of the second direction in plan view,
in the first direction, a range in which the first through hole and the second through hole are disposed overlaps a range in which the first bonding member is disposed, and
in the first direction, the range in which the first through hole and the second through hole are disposed overlaps a range in which the second bonding member is disposed.

6. The vibration device according to claim 1, wherein
the semiconductor substrate includes an oscillation circuit formed on the second face and electrically coupled to the first conductive layer.

7. The vibration device as claimed in claim 3, wherein
the semiconductor substrate includes an oscillation circuit formed on the second face and electrically coupled to the first conductive layer and the second conductive layer.

8. The vibration device according to claim 1, further comprising:
a lid bonded to the first face of the semiconductor substrate, wherein
the vibration element is housed in a space surrounded by the lid and the semiconductor substrate.

9. The vibration device according to claim 6, further comprising:
a lid bonded to the first face of the semiconductor substrate, wherein
the vibration element is housed in a space surrounded by the lid and the semiconductor substrate.

10. The vibration device according to claim 7, further comprising:
a lid bonded to the first face of the semiconductor substrate, wherein
the vibration element is housed in a space surrounded by the lid and the semiconductor substrate.
